(19) United States
(12) Patent Application Publication
(10) Pub. No.: US 2019/0056558 A1
(43) Pub. Date: Feb. 21, 2019

(54) Multiple laser system packaging

(71) Applicant: ROCKLEY PHOTONICS LIMITED, London (GB)

(72) Inventors: Andrew George Rickman, Marlborough (GB); Hooman Abediasl, Pasadena, CA (US)

(21) Appl. No.: 15/999,078

(22) Filed: Aug. 17, 2018

Related U.S. Application Data
(60) Provisional application No. 62/547,403, filed on Aug. 18, 2017.

(51) Int. Cl. G02B 6/43; G02B 6/42; H05K 13/00; G02B 6/12; H01L 23/00

(52) U.S. Cl. CPC G02B 6/43; G02B 6/428; H05K 13/00; G02B 2006/12121; H01L 24/49; G02B 2006/12061; G02B 2006/12135; G02B 6/12004

(57) ABSTRACT

A photonic chip comprising tunable lasers, emitters and other optical components such as waveguides, wavelength band combiners and wavelength lockers, is packaged with one or more complementary metal-oxide semiconductor chips in different ways. The complementary metal-oxide semiconductor chips are arranged on the sides or the bottom of the photonic chip. Through-Si-vias or wire bonding provides electrical contact between the photonic chip and the complementary metal-oxide semiconductor chips.

### CROSS REFERENCE TO RELATED APPLICATIONS

The present application claims priority to U.S. Provisional Patent Application No. 62/547,403, filed on Aug. 18, 2017, the disclosure of which is incorporated herein by reference in its entirety.

### TECHNICAL FIELD

The present disclosure relates to packaging for photonic systems. More particularly, it relates to multiple laser system packaging.

### BRIEF DESCRIPTION OF DRAWINGS

The accompanying drawings, which are incorporated into and constitute a part of this specification, illustrate one or more embodiments of the present disclosure and, together with the description of example embodiments, serve to explain the principles and implementations of the disclosure.

FIGS. 1 and 2 illustrate different configurations of a photonic chip and CMOS electronic chips.

FIG. 3 illustrates a top view of the photonic chips of FIGS. 1-2.

### DETAILED DESCRIPTION

The present disclosure describes methods to package laser systems comprising multiple lasers and photonic components with control circuits. For example, the photonic circuit may be fabricated on a photonic chip and comprise multiple lasers, waveguides and other components such as, for example, switches and wavelength lockers and emitters. For example, the photonic chip may be made of Si. The control circuits may be fabricated on one or more complementary metal-oxide semiconductor (CMOS) chips. The CMOS chips may be packaged with the photonic chip in different ways. The present disclosure describes some packaging methods and their advantages.

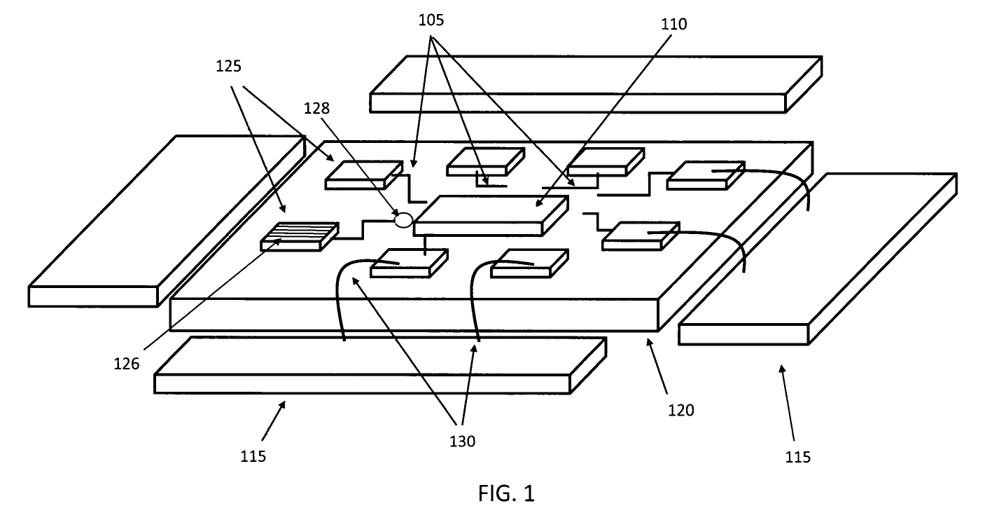

In the embodiment of FIG. 1, a first packaging arrangement is described. The photonic chip (120) may comprise a plurality of lasers, for example tunable lasers (125). In some embodiments, the lasers may be disposed symmetrically in the photonic chip area. For example, FIG. 1 illustrates an exemplary arrangement comprising two lasers for each side (lateral, all four directions) of the rectangular chip top surface area (for a total of eight lasers). The pitch or distance between lasers may be varied according to the application requirement. For example, the pitch may be increased or decreased. By decreasing the pitch, more lasers may be inserted on the chip, at the cost of, for example, increased thermal coupling between adjacent lasers, which may negatively affect performance. Some applications may be relatively unaffected by temperature changes. Therefore, in some applications the photonic chip may comprise thermal control, while in other applications no thermal control is necessary. The pitch and the laser density control the thermal and electrical isolation between lasers. In some embodiments, the pitch between lasers may be in the order of micrometers. In some embodiments, less than eight lasers may be included in the chip. For example, in FIG. 1, one or more of the eight lasers may be missing due to space or power requirements for the chip. In some embodiments, each laser is tunable. In some embodiments, each “laser” is actually an array of lasers (i.e. laser bar). In some embodiments, more than eight laser bars may be included on the photonic chip with more than five discrete lasers (126) per bar.

The use of tunable lasers allows for a decrease in the number of lasers necessary to provide the specific band of wavelengths required by the application. For example, the packaging arrangements described in the present disclosure may be used for LiDAR systems, laser spectroscopy systems (e.g. biosensors), or other types of systems comprising multiple lasers that use photonic integrated circuitry and have a common emitter area or emitter array system.

Photonic integrated circuitry is a device that includes photonic functions built into the circuitry. This can be built, for example, from lithium niobite, silica on silicon, silicon on insulator, polymers, and/or semiconductors such as GaAs (gallium arsenide) and InP (indium phosphide).

LiDAR (laser-based radar) is a method of surveying or imaging an area by the use of measuring the reflection of laser light off surfaces.

Spectroscopy is the method of determining characteristics of an object by measuring the spectra of light reflected off or transmitted through the object. Laser spectroscopy uses one or more lasers to illuminate the target object for the spectroscopy.

As known to the person of ordinary skill in the art, a normal arrangement would have the lasers on one side of the photonic chip, with the emitters on the opposite side. The arrangement of FIG. 1, by contrast, arranges the lasers (125) on all sides of the photonic chip, and places the emitters (110) in the middle. The lasers (125) provide photons to the emitters, through the photonic circuitry of the photonic chip, and the emitters (110) emit out of the plane of the top surface of the chip (120). Although in FIG. 1 the emitters (110) and the lasers (125) are illustrated as not in the same plane of the chip (120), this depiction is for emphasis only, and in reality, both the emitters and the lasers can be fabricated in the top surface of the photonic wafer. In some embodiments, the wafer may be a silicon on insulator (SOI) wafer. The tunable lasers are connected to the emitters through multiple waveguides (105). Additional photonic components (128) may also comprise wavelength lockers, wavelength band combiners and switches.

By arranging the lasers on all sides of the photonic chip (120), it is now possible to place one or more CMOS chips (115) on one or more of the lateral sides of the photonic chip (120). For example, CMOS chip may be placed per lateral side, or more than CMOS chip may be placed on the same lateral side, or some lateral sides may have CMOS chips. In this way, a wider area is available to connect the CMOS control circuitry to the chip (120). The CMOS circuitry can be used to control the different photonic components, such as lasers, switches, wavelength lockers and combiners. In the example of FIG. 1, four CMOS chips are arranged around the photonic chip, one on each of the four sides of the photonic chip. In some embodiments, the CMOS chips are connected to the relevant components on the photonic chip through wire bonding (130). The chip (120) can, alternatively, be connected to the CMOS chips (115) by package-on-package packaging where the CMOS chips are connected above the photonic chip rather than to the side, provided they do not block the emitters (110).

In some embodiments, the photonic chip (120) may have lateral dimensions of about 1×1 cm. The CMOS circuit will typically have lateral dimensions equal to or less than the lateral dimension of the photonic chip, in order to be able to arrange up to four CMOS chips around the photonic chip. For example, each CMOS chip may have lateral dimensions of a few millimeters by a few millimeters. In some embodiments, the wire bonds have a length which allows 1 Gb/s data rate transfer or less. In some embodiments, the CMOS chips are not in physical contact to the edges of the photonic chip but have a small gap in between. Laser dies typically have a footprint of few mm by a few mm supporting multiple channels. Silicon photonic die, depending on the complexity of the circuit, can also take up a footprint of a few of mm by a few mm, e.g. 10 mm².

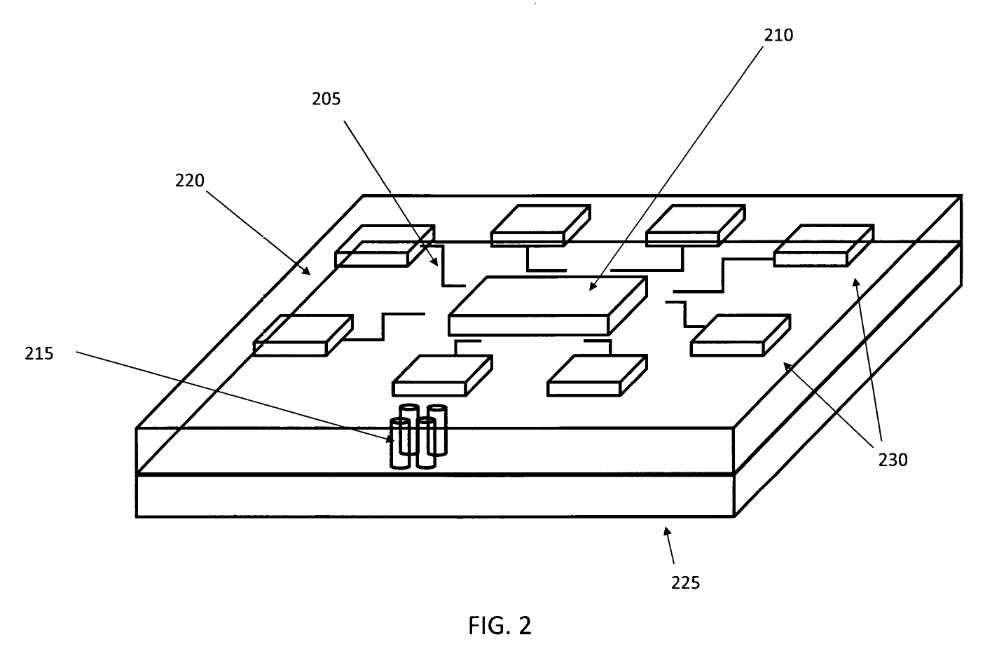

FIG. 2 illustrates an embodiment where the CMOS chip is placed on the bottom of the photonic chip instead of the sides or package-on-package. In FIG. 2, the CMOS chip (225) is in contact with the bottom surface of the photonic chip (220). For example, the two chips may be bonded or otherwise attached. Instead of using wire bonds as in FIG. 1, the configuration of FIG. 2 can use “through silicon (Si) vias” (TSV) to connect the CMOS control circuitry to the photonic components on the Si chip. The use of TSV (215) can be advantageous for certain applications requiring a high number of electrical interconnects.

In some embodiments, the configuration of FIG. 1 can be used for applications having higher or lower power requirements, while the configuration of FIG. 2 can be used for applications having low power requirements. For example, each laser generates a power of 1-10 mW. The lower power requirement is coupled with a decreased thermal coupling between lasers. Due to the decreased thermal energy generation, an active temperature control may not be required. Normally, the temperature control system is placed on the bottom surface of the photonic chip of FIG. 1. For the embodiments of FIG. 2, the bottom surface is occupied by the CMOS chip, making this configuration possible if the system does not require an active thermal control system attached to the bottom surface of the photonic chip.

In FIG. 2, other photonic components can be present, similarly to FIG. 1. For example, lasers (230), waveguides (205) and emitters (210) may be arranged similarly as in FIG. 1. The TSVs (215) in FIG. 2 are illustrated in a single position for clarity, to avoid cluttering the illustration. However, such TSVs can be placed at multiple locations. For example, each laser may have an adjacent TSV to connect to the CMOS circuitry.

In some embodiments, the photonic chip and the CMOS chip in FIG. 2 have a similar or equal area. For example, multiple systems may be fabricated on a single wafer. The matching area can be advantageous for wafer-level bonding, as it allows bonding of wafers having the same size. The bonding can be followed by dicing of the individual systems.

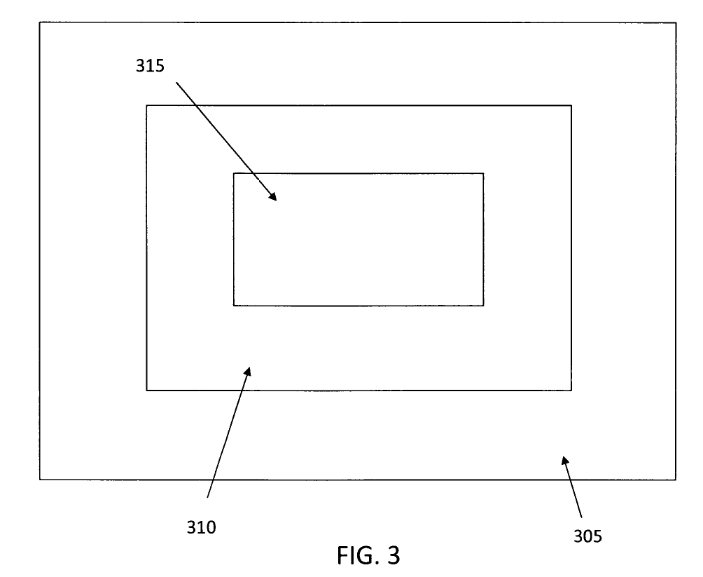

FIG. 3 illustrates a top view of the photonic chip of either FIG. 1 or 2. For example, the photonic chip may comprise a first area (305) where the lasers are located, a second area (315) where the emitters are located, and a third area (310) between the first and second area, where other photonic components are located, such as waveguides, combiners, switches and lockers.

In some embodiments, the TSV are filled with an electrical conductor, such as for example copper. In some embodiments, the vias are processed in the Si chip first, and then filled with an electrical conductor. Raised pads can be fabricated in the CMOS chip in locations corresponding to the vias. In this way, when the CMOS chip is bonded to the Si chip, the electrical pads in the CMOS chip make electrical contact to the TSVs in the Si chip.

The packaging described herein can be used, for example, to package optical phased arrays comprising multiple emitters, lasers and other optical components. Emitters typically emit electromagnetic radiation after processing by the other optical components. The radiation originates from the one or more lasers packaged in the system.

Optical components are photonic components, and do not necessarily have to operate in the visible spectrum. For example, the lasers can be IR (infrared) lasers.

FIG. 1 shows a rectangular shape for the chip, but other geometric shapes can be used based on performance benefit, for example adding trenches for better thermal isolation.

A number of embodiments of the disclosure have been described. Nevertheless, it will be understood that various modifications may be made without departing from the spirit and scope of the present disclosure. Accordingly, other embodiments are within the scope of the following claims.

The examples set forth above are provided to those of ordinary skill in the art as a complete disclosure and description of how to make and use the embodiments of the disclosure and are not intended to limit the scope of what the inventor/inventors regard as their disclosure.

Modifications of the above-described modes for carrying out the methods and systems herein disclosed that are obvious to persons of skill in the art are intended to be within the scope of the following claims. All patents and publications mentioned in the specification are indicative of the levels of skill of those skilled in the art to which the disclosure pertains. All references cited in this disclosure are incorporated by reference to the same extent as if each reference had been incorporated by reference in its entirety individually.

It is to be understood that the disclosure is not limited to particular methods or systems, which can, of course, vary. It is also to be understood that the terminology used herein is for the purpose of describing particular embodiments only and is not intended to be limiting. As used in this specification and the appended claims, the singular forms “a,” “an,” and “the” include plural referents unless the content clearly dictates otherwise. The term “plurality” includes two or more referents unless the content clearly dictates otherwise. Unless defined otherwise, all technical and scientific terms used herein have the same meaning as commonly understood by one of ordinary skill in the art to which the disclosure pertains.

The references in the present application, shown in the reference list below, are incorporated herein by reference in their entirety.

What is claimed is:

1. A structure comprising:
a photonic chip comprising a plurality of lasers on at least two of four lateral regions of a top surface of the photonic chip, a plurality of emitters in a central region of the top surface, and a plurality of waveguides on the top surface, the plurality of waveguides connecting the plurality of lasers to the plurality of emitters;
at least two complementary metal-oxide semiconductor (CMOS) chips, each CMOS chip arranged on a different side of the photonic chip; and
wire bonds connecting the at least two CMOS chips to the photonic chip.

2. The structure of claim 1, wherein the at least two CMOS chips comprise four CMOS chips.

3. The structure of claim 2, wherein the four CMOS chips comprise one CMOS chip per side of the photonic chip.

4. The structure of claim 1, wherein each of the plurality of lasers is tunable.

5. The structure of claim 4, wherein each of the plurality of lasers comprise a laser array.

6. The structure of claim 5, wherein each laser array comprises at least five discrete lasers.

7. The structure of claim 1, wherein the plurality of lasers comprises eight lasers.

8. The structure of claim 7, wherein the eight lasers are positioned on the photonic chip as two lasers per lateral side.

9. A structure comprising:
a photonic silicon (Si) chip comprising a plurality of lasers on at least two of four lateral regions of a top surface of the photonic Si chip, a plurality of emitters in a central region of the top surface, and a plurality of waveguides on the top surface, the plurality of waveguides connecting the plurality of lasers to the plurality of emitters;
a complementary metal-oxide semiconductor (CMOS) chip on a bottom surface of the photonic Si chip; and
through-Si-vias connecting the CMOS chip to the photonic Si chip.

10. A method comprising:
providing a photonic chip;
fabricating a plurality of lasers on at least two of four lateral regions of a top surface of the photonic chip, a plurality of emitters in a central region of the top surface, and a plurality of waveguides on the top surface, the plurality of waveguides connecting the plurality of lasers to the plurality of emitters;
providing at least two complementary metal-oxide semiconductor (CMOS) chips;
arranging each CMOS chip on a different side of the photonic chip; and
connecting by wire bonds the at least two CMOS chips to the photonic chip.

11. The method of claim 10, wherein the at least two CMOS chips comprise four CMOS chips.

12. The method of claim 11, wherein the four CMOS chips comprise one CMOS chip per side of the photonic chip.

13. The method of claim 10, wherein each of the plurality of lasers is tunable.

14. The method of claim 13, wherein each of the plurality of lasers comprise a laser array.

15. The method of claim 14, wherein each laser array comprises at least five discrete lasers.

16. The method of claim 10, wherein the plurality of lasers comprises eight lasers.

17. The method of claim 16, wherein the eight lasers are positioned on the photonic chip as two lasers per lateral side.

18. A method comprising:
providing a photonic Si chip;
fabricating a plurality of lasers on at least two of four lateral regions of a top surface of the photonic Si chip, a plurality of emitters in a central region of the top surface, and a plurality of waveguides on the top surface, the plurality of waveguides connecting the plurality of lasers to the plurality of emitters;
fabricating through-Si-vias in the photonic Si chip;
providing a complementary metal-oxide semiconductor (CMOS) chip;
bonding the CMOS chip on a bottom surface of the photonic Si chip; and
connecting the photonic Si chip to the CMOS chip through an electrical conductor in the through-Si-vias.
